(19) United States
(12) Patent Application Publication
(10) Pub. No.: US 2009/0159128 A1
(43) Pub. Date: Jun. 25, 2009

(54) LEADFRAME RECEIVER PACKAGE FOR SOLAR CONCENTRATOR

(76) Inventors: Gill Shook, Santa Cruz, CA (US); Eric Prather, Santa Clara, CA (US)

Correspondence Address: BUCKLEY, MASCHOFF & TALWALKAR LLC, 50 LOCUST AVENUE, NEW CANAAN, CT, 06840, US

(21) Appl. No.: 12/046,152

(22) Filed: Mar. 11, 2008

Related U.S. Application Data
(60) Provisional application No. 61/016,314, filed on Dec. 21, 2007.

(51) Int. Cl. H01L 31/024; H01L 31/048; H01L 31/18

(52) U.S. Cl. 136/259; 29/825

(57) ABSTRACT

A system includes a leadframe comprising a first conductive element, a solar cell electrically coupled to the first conductive element and comprising an active area, and mold compound disposed on the leadframe and the solar cell. The mold compound defines a first aperture over at least a portion of the active area and a second aperture over at least a portion of the first conductive element.

### CROSS-REFERENCE TO RELATED APPLICATION

The present application claims priority to U.S. Provisional Patent Application Ser. No. 61/016,314, filed on Dec. 21, 2007 and entitled “Leadframe Receiver Package For Solar Concentrator”, the contents of which are incorporated herein by reference for all purposes.

### BACKGROUND

A solar cell requires some manner of integrated circuit package for use within a power-generating system. The package may provide environmental protection, heat dissipation, electrical connectivity and/or other functions to the solar cell. The package may also or alternatively provide structure(s) to facilitate proper positioning of the solar cell with respect to other components of the system.

A concentrating solar power unit may operate to concentrate incoming light onto a solar cell. This concentrated light, which may exhibit the power per unit area of 500 suns, requires a solar cell package which can withstand such intensity over an operational lifetime. The package must also be capable of supporting high power levels generated by systems in which the concentrating solar power unit will typically be implemented.

Conventional attempts to address the foregoing issues have led to solar cell packages which are expensive due to material costs and/or manufacturing difficulties. What is needed is an improved solar cell package for use in a solar concentrator. Such a system may improve manufacturability, cost, operational lifetime, alignment, power generation efficiency, power dissipation and/or electromagnetic isolation.

### BRIEF DESCRIPTION OF THE DRAWINGS

FIG. 1 is a perspective top view of a partially-assembled integrated circuit package according to some embodiments.

FIG. 2 is a perspective top view of an integrated circuit package according to some embodiments.

FIG. 3 is a cutaway side view of an integrated circuit package according to some embodiments.

FIG. 4 is a top view of a portion of a panel strip according to some embodiments.

FIG. 5 is a cutaway side view of an integrated circuit package and optical element according to some embodiments.

FIG. 6 is a cutaway side view of an integrated circuit package according to some embodiments.

FIG. 7 is a top view of a leadframe according to some embodiments.

FIG. 8 is a top perspective view of a leadframe and a solar cell according to some embodiments.

FIG. 9 is a top perspective view of a leadframe, a solar cell and a bottom-side conductor according to some embodiments.

FIG. 10 is a perspective top view of an integrated circuit package according to some embodiments.

### DESCRIPTION

The following description is provided to enable any person in the art to make and use the described embodiments and sets forth the best mode contemplated for carrying out some embodiments. Various modifications, however, will remain readily apparent to those in the art.

FIG. 1 is a perspective view of a portion of integrated circuit package 100 according to some embodiments. Package 100 comprises substrate 110 and solar cell 120. Substrate 110 may comprise molded material such as epoxy mold compound or any other suitable material that is or becomes known. Substrate 110 supports leadframe elements 135, 140 and 150a and 150b. The leadframe elements may be etched or stamped from a conductive panel strip using known leadframe manufacturing techniques.

Solar cell 120 may comprise a III-V solar cell, a II-VI solar cell, a silicon solar cell, or any other type of solar cell that is or becomes known. Solar cell 120 may comprise any number of active, dielectric and metallization layers, and may be fabricated using any suitable methods that are or become known. Solar cell 120 is capable of generating charge carriers (i.e., holes and electrons) in response to received photons.

Conductive terminals 125a and 125b are disposed on an upper side of solar cell 120. Each of conductive terminals 125a and 125b may comprise any suitable metal contact, and may include a thin adhesion layer (e.g., Ni or Cr), an ohmic metal (e.g., Ag), a diffusion barrier layer (e.g., TiW or TiW:N), a solderable metal (e.g., Ni), and a passivation metal (e.g., Au). Wirebonds 130a and 130b electrically couple conductive terminals 125a and 125b to conductive leadframe element 135. Conductive terminals 125a and 125b therefore exhibit a same polarity according to some embodiments.

A further conductive terminal (not shown) may be disposed on a lower side of solar cell 120. This conductive terminal may exhibit a polarity opposite from the polarity of conductive terminals 125a and 125b. This conductive terminal is coupled to conductive leadframe element 140 using silver die attach epoxy or solder according to some embodiments. Embodiments are not limited to the illustrated shapes and relative sizes of conductive elements 135 and 140.

By virtue of the foregoing arrangement, current may flow between conductive elements 135 and 140 while solar cell 120 actively generates charge carriers. If solar cell 120 is faulty or otherwise fails to generate charge carriers, bypass diode 145 may electrically couple conductive element 135 to conductive element 140 in response to a received external signal.

Device 100 also includes leadframe tiebar elements 150a and 150b disposed on molded substrate 110. Leadframe tiebar elements 150a and 150b will be described further below.

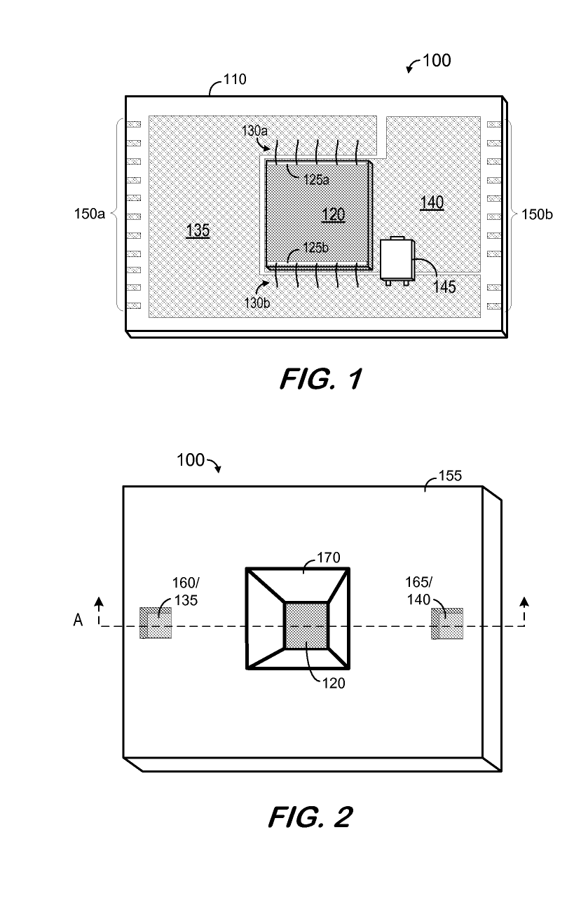

FIG. 2 is a top view of assembled package 100 according to some embodiments. Mold compound 155, which may comprise any suitable material, has been molded over the FIG. 1 device. Also shown are apertures 160 and 165 defined by mold compound 155. Conductive element 135 and conductive element 140 are respectively exposed by apertures 160 and 165. Heat shield 170 is disposed in another aperture of compound 155 so as to expose an active area of solar cell 120. Any percentage of the active area of solar cell 120, including 100%, may be visible through heat shield 170 according to some embodiments. An inner portion of heat shield 170 may be reflective (i.e., coated or natively reflective) to assist in directing incoming light to the active area.

Heat shield 170 may be co-molded with compound 155 according to some embodiments. Apertures 160 and 165 may be defined during or after this co-molding using known molding techniques. According to some embodiments, an upper surface of compound 155 is light-colored to assist in reflecting solar energy incident thereon. Mold compound 155 may have a high thermal conductivity in some embodiments to assist dispersion of heat from incident solar energy.

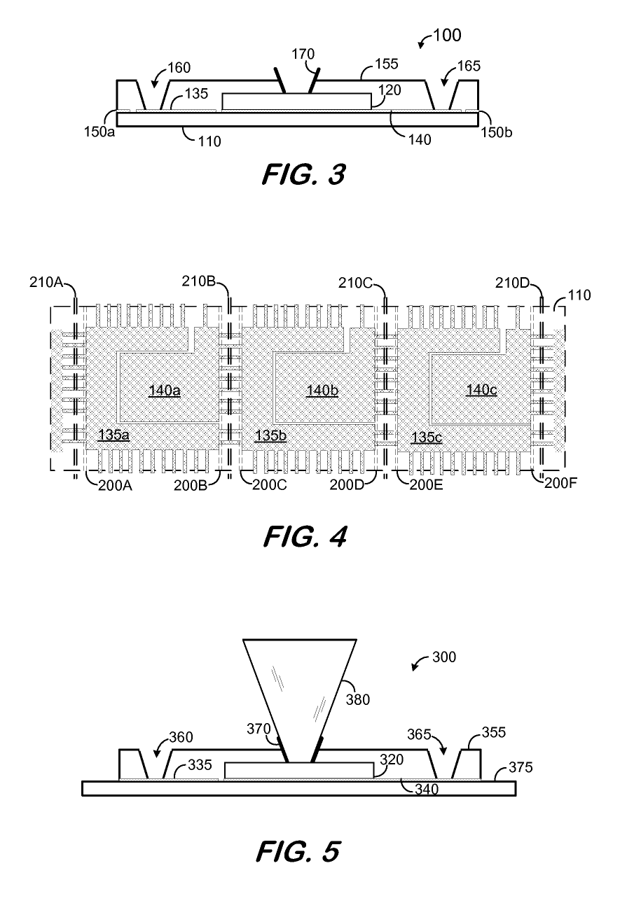

FIG. 3 is a view of cross-section A of FIG. 2. FIG. 3 illustrates leadframe elements 135, 140 and 150a and 150b disposed on molded substrate 110. Also shown are apertures 160 and 165 and heat shield 170. In some embodiments, substrate 110 of the FIG. 2/3 device is mounted to a heat spreader or other conductive element. The risk of arcing between leadframe elements 135 or 140 and the conductive element is reduced due to apertures 160 and 165. In this regard, the effective distance between either of elements 135 or 140 and the conductive element includes the depth of the aperture in which the element resides.

FIGS. 1 and 3 also show gap 152a between elements 150a and conductive element 135, and gap 152b between elements 150b and conductive element 140. Gaps 152a and 152b may provide electrical isolation of elements 150a and 150b, while also allowing the existence of a less sensitive edge area for handling device 100.

FIG. 4 is a top view of a conductive panel strip (e.g., copper) for explaining fabrication of device 100 according to some embodiments. The shaded elements represent portions of the panel strip which remain after etching, stamping, and/or other fabrication steps. Leadframe elements of three devices are illustrated, but a panel strip may include elements for any number of devices.

According to some embodiments, mold compound 110 or another insulating substrate is molded to the panel strip after fabrication of the leadframe elements. Next, the panel strip is cut along lines 200A through 200F to create gaps such as gaps 152a and 152b of device 100. This cut does not cut completely through substrate 110, but electrically disconnects elements 150a (150b) from element 135 (140).

Solar cells are attached to conductive elements 140a through 140c and the entire strip is subjected to a molding process to fabricate mold compound 155 including heat shield 170 and defining apertures 160 and 165. In some embodiments, heat shield 170 comprises a reflective thin film applied after molding of mold compound 155. The devices of the panel strip are then singulated by cutting along lines 210A through 210D.

FIG. 5 is a cutaway view of device 300 according to some embodiments. Device 300 includes leadframe elements 335 and 340 corresponding to elements 135 and 140 of device 100, but does not include structures corresponding to elements 150a and 150b. According, the panel strip of FIG. 4 may be singulated along lines 200A through 200F in order to produce devices such as device 300.

Conductive elements 335 and 340 and coupled to insulating substrate 375, which may or may not comprise mold compound. Substrate 375 may in turn be coupled to a heat spreader in some embodiments. According to some embodiments, electrical isolation between the heat spreader and elements 335 and 340 may be further improved by disposing an insulator (e.g., silicone) within apertures 360 and 365. Insulated wires may be coupled to elements 335 and 340 through apertures 360 and 365 prior to such filling.

Optical element 380 is coupled to heat shield 370. Optical element 380 may increase an acceptance angle of the concentrating solar radiation collector, homogenize incoming concentrated light over the surface of solar cell 320, and/or further concentrate the light. Heat shield 370 may assist in retaining element 380 is a suitable position. A similar optical element may be coupled to heat shield 120 of device 100. In some embodiments, the heat shield does not contact the optical element but protects the adjacent mold compound from heat (i.e., stray light).

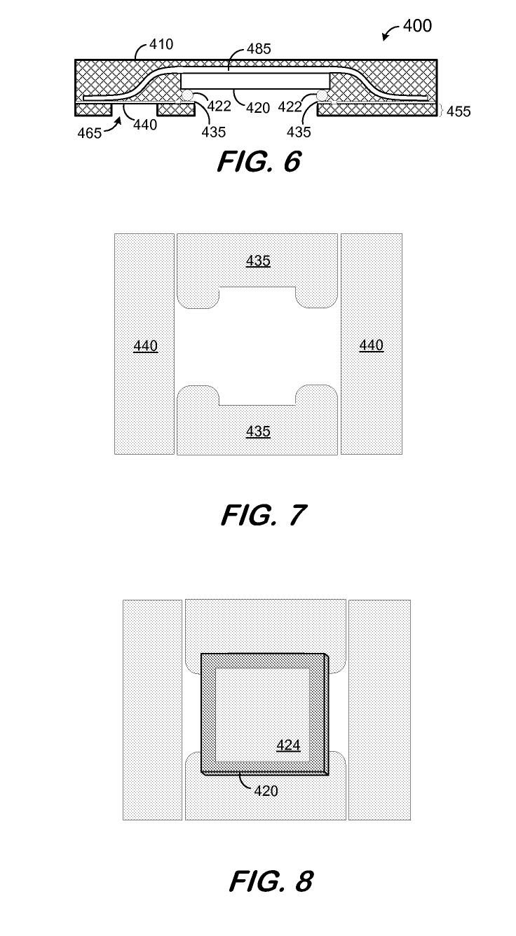

FIG. 6 is a side view of device 400 according to some embodiments. Device 400 includes mold compound 410 disposed over flip chip solar cell 420. Also shown are leadframe conductive elements 435 and 440 as well as mold compound 455 defining aperture 465. Device 400 further includes heat spreader/bottom-side contact 485. Contact may comprise any conductive material exhibiting suitable thermal conductivity.

As will be described below and clearly illustrated in subsequent figures, solder bumps 420 are electrically coupled to elements 435 and contact 485 is electrically coupled to elements 440. In this regard, FIG. 7 is a top view of leadframe elements of device 400 according to some embodiments. FIG. 8 is a top perspective view showing solar cell 420 after coupling solder bumps 422 to elements 435. Bottom-side contact 424 of solar cell 420 is also visible.

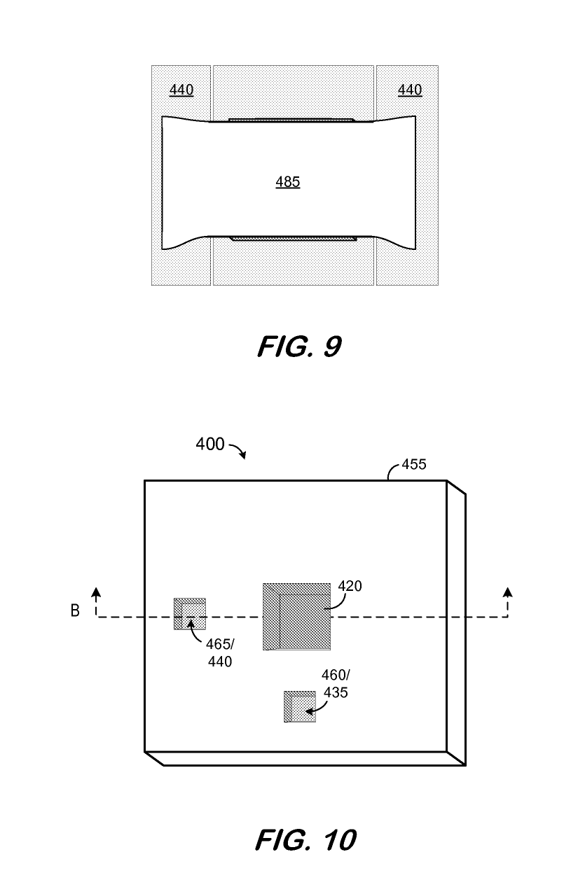

FIG. 9 shows contact 485 after attachment to bottom-side contact 424 and conductive elements 440. Accordingly, contact 485 and elements 440 exhibit a first polarity and elements 435 and solder bumps 422 exhibit a second polarity.

FIG. 10 is a top perspective view of device 400 according to some embodiments. More specifically, mold compound 410 has been applied over contact 385 and mold compound 455 has been applied to the other side of elements 335 and 340. FIG. 10 is therefore a view of an opposite side of device 400 that that shown in FIGS. 8 and 9. For further clarity, it is noted that FIG. 6 is a cutaway view at cross-section B shown in FIG. 10.

Mold compound 455 defines apertures 460 and 465. Conductive element 435 and conductive element 440 are respectively exposed by apertures 460 and 465. An active area of solar cell 120 is also exposed by mold compound 455. Some embodiments of device 400 further include a heat shield as described above.

The several embodiments described herein are solely for the purpose of illustration. Embodiments may include any currently or hereafter-known versions of the elements described herein. Therefore, persons in the art will recognize from this description that other embodiments may be practiced with various modifications and alterations.

What is claimed is:

1. An apparatus comprising:
a leadframe comprising a first conductive element;
a solar cell electrically coupled to the first conductive element and comprising an active area; and
mold compound disposed on the leadframe and the solar cell, the mold compound defining a first aperture over at least a portion of the active area and a second aperture over at least a portion of the first conductive element.

2. An apparatus according to claim 1, further comprising:
a shield element co-molded into the mold compound within the first aperture, the shield element to receive an optical element.

3. An apparatus according to claim 1,
wherein the leadframe comprises a second conductive element electrically isolated from the first conductive element, and
wherein the mold compound defines a third aperture over at least a portion of the second conductive element and on a same side of the leadframe as the first aperture and the second aperture.

4. An apparatus according to claim 3,
wherein a first conductive terminal of the solar cell exhibiting a first polarity is coupled to the first conductive element, and
wherein a second conductive terminal of the solar cell exhibiting a second polarity is coupled to the second conductive element.

5. An apparatus according to claim 3, further comprising:
leadframe tiebar elements that are electrically isolated from the first conductive element and from the second conductive element.

6. An apparatus according to claim 1, further comprising:
an insulating substrate coupled to a side of the leadframe opposite the solar cell; and
a heat sink coupled to the insulating substrate.

7. An apparatus according to claim 1, further comprising:
a wire electrically coupled to the first conductive element, a portion of the wire passing through the second aperture; and
an insulator disposed in the second aperture and surrounding the portion of the wire.

8. An apparatus according to claim 1,
wherein the leadframe comprises a second conductive element electrically isolated from the first conductive element, and
wherein the solar cell comprises:
a first conductive terminal disposed on a same side of the solar cell as the active area, exhibiting a first polarity, and electrically coupled to the first conductive element; and
a second conductive terminal disposed on an opposite side of the solar cell as the active area and exhibiting a second polarity,
the apparatus further comprising:
an electrically conductive heat spreader electrically coupled to the second conductive element and to the second conductive terminal,
wherein the mold compound defines a third aperture over at least a portion of the second conductive element and on a same side of the leadframe as the first aperture and the second aperture.

9. An apparatus according to claim 1, wherein the mold compound is light-colored.

10. A method comprising:
fabricating a leadframe comprising a first conductive element;
electrically coupling a solar cell comprising an active area to the first conductive element; and
molding mold compound on the leadframe and the solar cell, the molded mold compound defining a first aperture over at least a portion of the active area and a second aperture over at least a portion of the first conductive element.

11. A method according to claim 10, wherein molding the mold compound comprises:
molding a shield element into the mold compound within the first aperture, the shield element to receive an optical element.

12. A method according to claim 10,
wherein the fabricated leadframe comprises a second conductive element electrically isolated from the first conductive element, and
wherein the molded mold compound defines a third aperture over at least a portion of the second conductive element and on a same side of the leadframe as the first aperture and the second aperture.

13. A method according to claim 12, wherein electrically coupling the solar cell to the first conductive element comprises electrically coupling a first conductive terminal of the solar cell exhibiting a first polarity to the first conductive element,
the method further comprising:
electrically coupling a second conductive terminal of the solar cell exhibiting a second polarity to the second conductive element.

14. A method according to claim 12, further comprising:
coupling an insulating substrate to a side of the leadframe opposite the solar cell;
electrically isolating leadframe tiebar elements from the first conductive element and from the second conductive element; and
singulating the first conductive element, the second conductive element, the solar cell, the mold compound and the isolated leadframe tiebar elements as a single device.

15. A method according to claim 14, further comprising:
coupling a heat sink to the insulating substrate.

16. A method according to claim 10, further comprising:
electrically coupling a wire to the first conductive element, wherein a portion of the wire passes through the second aperture; and
disposing an insulator in the aperture and surrounding the portion of the wire.

17. A method according to claim 10,
wherein fabricated leadframe comprises a second conductive element electrically isolated from the first conductive element,
wherein the solar cell comprises:
a first conductive terminal disposed on a same side of the solar cell as the active area, exhibiting a first polarity, and electrically coupled to the first conductive element; and
a second conductive terminal disposed on an opposite side of the solar cell as the active area and exhibiting a second polarity, and
wherein the molded mold compound defines a third aperture over at least a portion of the second conductive element and on a same side of the leadframe as the first aperture and the second aperture,
the method further comprising:
electrically coupling a electrically conductive heat spreader to the second conductive element and to the second conductive terminal.

18. A method according to claim 10, further comprising
molding mold compound over at least a portion of the electrically conductive heat spreader.
